(19) United States
(12) Patent Application Publication
(10) Pub. No.: US 2025/0150022 A1
(43) Pub. Date: May 8, 2025

(54) ROOFING SYSTEM WITH VISUALLY MATCHING ROOFING PANELS AND METHOD OF INSTALLATION

(71) Applicant: CERTAINTEED LLC, Malvern, PA (US)

(72) Inventors: Sahas RATHI, Shrewsbury, MA (US); Vural KARA, Northborough, MA (US); Phillip EVANS, Littleton, MA (US); Hooman AMID, Worcester, MA (US); Garrett LOOMIS, Brighton, MA (US)

(21) Appl. No.: 18/837,919

(22) PCT Filed: Feb. 16, 2023
(86) PCT No.: PCT/US2023/062722

§ 371 Date: Aug. 13, 2024

Related U.S. Application Data
(60) Provisional application No. 63/311,293, filed on Feb. 17, 2022.

(51) Int. Cl. H02S 20/25; E04D 1/16; H10F 19/80

(52) U.S. Cl. CPC H02S 20/25; E04D 1/16; H10F 19/804

(57) ABSTRACT

The present disclosure relates generally to roofing systems, for example, suitable for covering the roof of a house or other building. The present disclosure relates more particularly to a roofing system including first and second group of roofing panels. Each roofing panel of the first group is a solar roofing panel and includes a light transmissible front layer, a back layer, photovoltaic cells disposed between a rear surface of the front layer and a front surface of the back layer, and a color-matching surface disposed behind the front layer. Each roofing panel of the second group is a cuttable non-solar roofing panel and includes a cuttable substrate. Visual characteristics of a front face of the roofing panels of the first group and a front face of roofing panels of the second group match.

### TECHNICAL FIELD

The present disclosure relates generally to roofing systems, for example, suitable for covering the roof of a house or other building. The present disclosure relates more particularly to a roofing system comprising a plurality of roofing panels with different configurations.

### BACKGROUND ART

Demand for renewable energy sources, such as solar, wind, and hydropower, continues to grow. Accordingly, the use of photovoltaic cells on roofs is becoming increasingly common, in order to utilize solar energy within buildings and homes. A conventional technique for utilizing photovoltaic cells on roofs is to secure solar panels on top of a complete and enclosed roof system. This technique is effective and has been popular because it allows the solar panels to be added to a roof and to continue utilizing the existing roof structure.

With certain roof designs, the roof is visible from the ground, such as with sloped roofs. In these cases, any solar panels placed on top of the roof will also be visible from the ground. In many instances, the inclusion of solar panels on top of an existing roof structure is inconsistent with the original architectural aesthetic of the building or house, and may be considered undesirable.

Another alternative for utilizing photovoltaic cells on a roof is to include the photovoltaic cells within the roofing system itself, such as in roofing panels or shingles applied over the roof. Such a system allows for a more consistent aesthetic over the surface of the roof compared with systems that include solar panels over the roofing structure. However, roofing panels or shingles that include photovoltaic cells are typically visually identifiable as different from other roofing panels or systems. Therefore, the present inventors have determined that a roofing system including solar roofing panels with improved aesthetics would be attractive to builders and customers.

### SUMMARY

In one aspect, the present disclosure provides a roofing system comprising a plurality of roofing panels comprising:
a first group of roofing panels, wherein each roofing panel of the first group is a solar roofing panel and includes:
   a light transmissible front layer having a front surface and a rear surface,
   a back layer having a front surface and a rear surface,
   photovoltaic cells disposed between the rear surface of the front layer and the front surface of the back layer, and
   a color-matching surface disposed behind the front layer;
a second group of roofing panels, wherein each roofing panel of the second group is a cuttable non-solar roofing panel and includes:
   a cuttable substrate,
wherein visual characteristics of a front face of the roofing panels of the first group and a front face of roofing panels of the second group match.

In another aspect, the disclosure provides a method of installing a roofing system according to the disclosure, the method comprising:
arranging a first group of roofing panels on a support structure, wherein each roofing panel of the first group is a solar roofing panel and includes:
   a front layer having a front surface and a rear surface,
   a back layer having a front surface and a rear surface,
   photovoltaic cells disposed between the rear surface of the front layer and the front surface of the back layer, and
   a color-matching surface disposed behind the front layer;
cutting a plurality of other roofing panels so as to form a second group of roofing panels, wherein each roofing panel of the second group is a cuttable non-solar roofing panel and includes a cuttable substrate; and
arranging the second group of roofing panels on the support structure;
wherein visual characteristics of a front face of the roofing panels of the first group and a front face of roofing panels of the second group match.

Additional aspects of the disclosure will be evident from the disclosure herein.

### BRIEF DESCRIPTION OF THE DRAWINGS

The accompanying drawings are included to provide a further understanding of the methods and devices of the disclosure, and are incorporated in and constitute a part of this specification. The drawings are not necessarily to scale, and sizes of various elements may be distorted for clarity. The drawings illustrate one or more embodiment(s) of the disclosure, and together with the description serve to explain the principles and operation of the disclosure.

FIG. 1 is a schematic perspective view of a roofing system according to an embodiment of the disclosure;

FIG. 2 is a schematic cross-sectional view of a portion of a roofing panel according to an embodiment of the disclosure;

FIG. 3 is a schematic cross-sectional view of a portion of a roofing panel according to an embodiment of the disclosure;

FIG. 4 is a schematic cross-sectional view of a portion of a roofing panel according to an embodiment of the disclosure;

FIG. 5 is a schematic cross-sectional view of a portion of a roofing panel according to an embodiment of the disclosure;

FIG. 6 is a schematic cross-sectional view of a portion of a roofing panel according to an embodiment of the disclosure;

FIG. 7 is a schematic cross-sectional view of a portion of a roofing panel according to an embodiment of the disclosure;

FIG. 8 is a schematic cross-sectional view of a portion of a roofing panel according to an embodiment of the disclosure;

FIG. 9 is a schematic cross-sectional view of the edges of a roofing panel according to an embodiment of the disclosure;

FIG. 10 is a schematic cross-sectional view of a portion of a roofing panel according to an embodiment of the disclosure;

FIG. 11 is a schematic cross-sectional view of a portion of a roofing panel according to an embodiment of the disclosure;

FIG. 12 is a schematic cross-sectional view of a portion of a roofing panel according to an embodiment of the disclosure;

FIG. 13 is a schematic cross-sectional view of a portion of a roofing panel according to an embodiment of the disclosure; and

FIG. 14 is a schematic cross-sectional view of a portion of a roofing panel according to an embodiment of the disclosure.

### DETAILED DESCRIPTION OF THE PREFERRED EMBODIMENT(S)

As described above, the present inventors have determined that a roofing system including solar roofing panels with improved aesthetics would be attractive to builders and customers.

Accordingly, one aspect of the disclosure is a roofing system that includes a plurality of roofing panels including a first group and a second group. Each roofing panel of the first group is a solar roofing panel and includes a light transmissible front layer having a front surface and a rear surface, a back layer having a front surface and a rear surface, photovoltaic cells disposed between the rear surface of the front layer and the front surface of the back layer, and a color-matching surface disposed behind the front layer. Further, each roofing panel of the second group is a cuttable non-solar roofing panel and includes a cuttable substrate. The front face of the roofing panels of the first group and a front face of roofing panels of the second group have matching visual characteristics.

The color-matching surface as described herein refers to a surface that matches the color of the surface of the photovoltaic cells by having a color difference CIEDE2000 of no more than 10 as measured according to the CIE Colorimetry Technical Report (4^{th} Edition) using a 2° standard colorimetric observer, a CIE standard illuminant D65, and any of di:8°, de:8° or 45 degree directional geometry. In some embodiments, the color-matching surface and photovoltaic cells have a color difference CIEDE2000, as measured under these same conditions, of no more than 6, for example no more than 3.

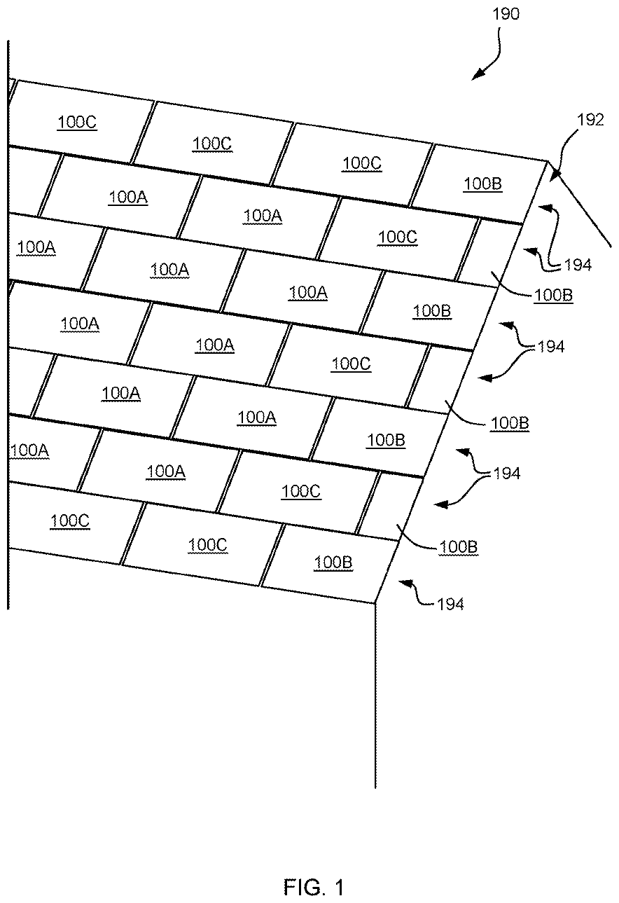

Such a roofing system is shown in perspective view in FIG. 1. Roofing system 190 includes a plurality of roofing panels 100A-100C arranged on a support structure 192. The plurality of roofing panels includes a first group of roofing panels 100A, each of which is a solar roofing panel, a second group of roofing panels 100B, each of which is a cuttable non-solar roofing panel, and a third group of roofing panels 100C, each of which is a non-solar roofing panel that may or may not be cuttable. The roofing panels of roofing system 190 have matching aesthetics. For example, the front surface of the roofing panels 100A of the first group have visual characteristics that match the front surface of the roofing panels 100B of the second group, as explained in more detail below.

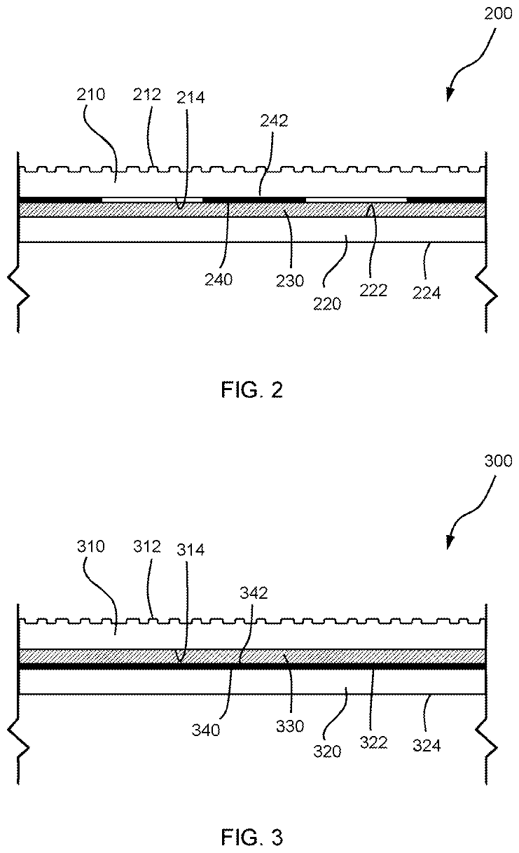

As stated above, each of the roofing panels in the first group has a light transmissible front layer, a back layer, photovoltaic cells disposed between the front layer and the back layer, and a color-matching surface disposed behind the front layer. FIGS. 2 through 7 each illustrate a portion of a cross section of an embodiment of such a roofing panel.

The color-matching surface as described herein provides visual characteristics to the roofing panels so that the areas surrounding the photovoltaic cells may have similar visual characteristics to those of the areas of the photovoltaic cells. For example, in some embodiments, the photovoltaic cells are black or very dark and the color-matching surface of the roofing panels helps provide a substantially uniform appearance across the surface of the roofing panel.

FIG. 2 shows a portion of a cross section of a roofing panel 200 that includes a front layer of glass 210, a back layer of glass 220, photovoltaic cells 230 and a visible layer 240 that forms a color-matching surface 242. Front layer of glass 210 includes a front surface 212 and a rear surface 214. Likewise, back layer of glass 220 also includes a front surface 222 and a rear surface 224. Photovoltaic cells 230 are positioned between rear surface 214 of the front layer of glass 210 and front surface 222 of back layer of glass 220. The visible layer 240 is positioned adjacent to rear surface 214 of front layer of glass 210 and can be seen through front layer of glass 210.

FIG. 3 shows a portion of a cross section of another roofing panel 300 that includes a front layer of glass 310 having a front surface 312 and a rear surface 314 and a back layer of glass 320 having a front surface 322 and a rear surface 324. Photovoltaic cells 330 are positioned between rear surface 314 of the front layer of glass 310 and front surface 322 of back layer of glass 320. Likewise, a color-matching surface 342 is provided by a visible layer 340 that is positioned adjacent to front surface 322 of back layer of glass 320. The term visible layer, as used herein, refers to a layer that includes a color-matching surface and is not transparent. However, portions of the visible layer may be obscured, for example by photovoltaic cells or other layers.

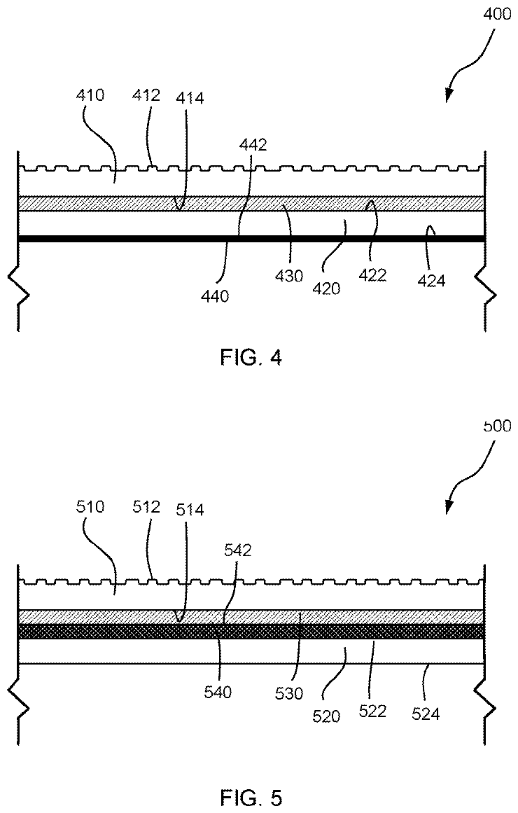

FIG. 4 shows a portion of a cross section of another roofing panel 400 that includes a front layer of glass 410 having a front surface 412 and a rear surface 414, and a back layer of glass 420 having a front surface 422 and a rear surface 424. Roofing panel 400 also includes photovoltaic cells 430 and a visible layer 440 that forms a color-matching surface 442. Photovoltaic cells 430 are positioned between rear surface 414 of the front layer of glass 410 and front surface 422 of back layer of glass 420. The visible layer 440 is positioned adjacent to rear surface 424 of back layer of glass 420.

FIG. 5 shows a portion of a cross section of a roofing panel 500 that is similar to roofing panel 300. Roofing panel 500 includes a front layer of glass 510, a back layer of glass 520, photovoltaic cells 530 and a visible layer 540 that forms a color-matching surface 542. Front layer of glass 510 includes a front surface 512 and a rear surface 514. Likewise, back layer of glass 520 also includes a front surface 522 and a rear surface 524. Photovoltaic cells 530 are positioned between rear surface 514 of the front layer of glass 510 and front surface 522 of back layer of glass 520. The visible layer 540 is positioned adjacent to front surface 522 of back layer of glass 520.

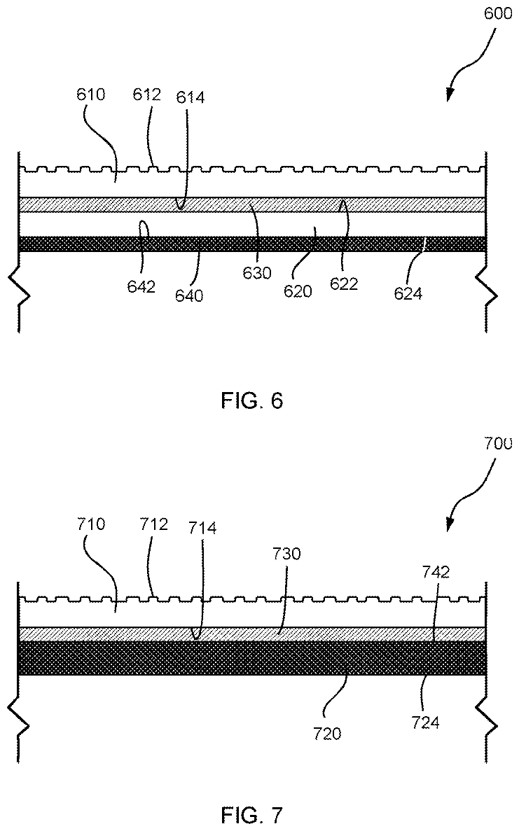

FIG. 6 shows a portion of a cross section of a roofing panel 600 that is similar to roofing panel 400. Roofing panel 600 includes a front layer of glass 610, a back layer of glass 620, photovoltaic cells 630 and a visible layer 640 that forms a color-matching surface 642. Front layer of glass 610 includes a front surface 612 and a rear surface 614. Likewise, back layer of glass 620 also includes a front surface 622 and a rear surface 624. Photovoltaic cells 630 are positioned between rear surface 614 of the front layer of glass 610 and front surface 622 of back layer of glass 620. The visible layer 640 is positioned adjacent to rear surface 624 of back layer of glass 620.

FIG. 7 shows a portion of a cross section of another roofing panel 700 that includes a front layer of glass 710, photovoltaic cells 730 and a back layer 720. The front layer of glass 710 has a front surface 712 and a rear surface 714. The back layer 720 has a color-matching surface 742 on its front side and a rear surface 724. Photovoltaic cells 730 are positioned between rear surface 714 of the front layer of glass 710 and the color-matching surface 742 of back layer 720.

In embodiments of the roofing panels described herein, the above-described layers within the roofing panels may be directly secured to one another or secured to one another using intermediate layers, such as adhesive layers. Further still, embodiments of the solar panels may include additional layers with the solar panels.

In certain embodiments of the roofing system as otherwise described herein, the color-matching surface of each roofing panel of the first group is formed by a coating. For example, in roofing panel 200, visible layer 240 is applied as a coating over the rear surface 214 of front layer of glass 210 and forms color-matching surface 242. Similarly, the visible layer 340 of roofing panel 300 is formed as a coating over the front surface 322 of back layer of glass 320 and forms color-matching surface 342. Likewise, the visible layer 440 of roofing panel 400 is formed as a coating over the rear surface 424 of the back layer of glass 420 and forms color-matching surface 442. In each case, the coating is provided on the front or back layer, which may provide structural support for the coated visible layer. For example, the color-matching surface may be applied as a liquid or a film over the respective front or back layer. In some embodiments, the visible layer may be provided directly on a surface of the front or back layer, while in other embodiments, one or more additional layers, such as other coating layers, may be provided between the respective front or back layer of glass and the visible layer.

In certain embodiments of the roofing system as otherwise described herein, the coating includes a pattern associated with the shape of the photovoltaic cells. For example, in some embodiments, the visible layer is provided in a pattern, for example by printing the visible layer, over the front or back layer. The pattern may be provided across the associated front or back layer to cover areas between the photovoltaic cells but include openings in the pattern that align with the photovoltaic cells. In some embodiments, the patterned visible layer is formed in front of the photovoltaic cells and the openings allow light to pass through to the photovoltaic cells. In other embodiments, the patterned visible layer is provided behind the photovoltaic cells, in which case the openings may reduce the amount of material used to form the layer, and avoid unnecessarily providing material for the visible layer in areas that will be obscured by the photovoltaic cells.

In other embodiments, the coating of the visible layer extends across the roofing panel. For example, in some embodiments, the visible layer covers an entire surface of the back layer. For example, visible layer 340 of roofing panel 300 is provided over the front surface 322 of back layer 320. On the other hand, visible layer 440 of roofing panel 400 is provided over the rear surface 424 of back layer 420. By providing the visible layer over a surface of the back layer, as in roofing panels 300 and 400, the visible layer can help provide the roofing panel with a relatively uniform appearance without hindering light from reaching the photovoltaic cells.

In certain embodiments of the roofing system as otherwise described herein, the coating is an inorganic enamel coating. In other embodiments, the visible layer may be formed by another material, such as a pigment-loaded polymer.

In certain embodiments of the roofing system as otherwise described herein, the color-matching surface of each roofing panel of the first group is formed by an opaque substrate. The term opaque substrate, as used herein, refers to a substrate that substantially blocks light in the visible spectrum, such as at least 95% of incident light. In some embodiments, the opaque substrate is disposed between the photovoltaic cells and the back layer of glass. For example, in roofing panel 500, visible layer 540 that forms color-matching surface 542 is formed of an opaque substrate that is positioned between the front surface 522 of the back layer of glass 520 and the photovoltaic cells. In other embodiments, the opaque substrate is disposed behind the back layer. For example, in roofing panel 600, visible layer 640 is also formed of an opaque substrate that is positioned behind the back layer 620. Further, in roofing panel 600, the opaque substrate 640 forms the rear surface of the roofing panel.

In certain embodiments of the roofing system as otherwise described herein, the opaque substrate is formed of a polymer material. For example, in some embodiments, the opaque substrate is formed of a glass-reinforced epoxy resin, such as FR4. In other embodiments, the opaque substrate includes another fiber-reinforced polymer or a layered structure. As examples, the opaque substrate may include any of PVDF, PET, PPE, polyphenylene oxide, polyphenylene sulfide, or other materials. Still, in other embodiments, the opaque substrate is made of another material, such as a ceramic or composite material.

In certain embodiments of the roofing system as otherwise described herein, at least one of the front layer and the back layer of each roofing panel of the first group is formed of glass. Further, in some embodiments at least one of the front layer and the back layer is formed of tempered glass. For example, in some embodiments, both the front layer and the back layer are formed of tempered glass. Tempered glass may add strength to the roofing panels and improve impact resistance.

In certain embodiments of the roofing system as otherwise described herein, the color-matching surface of each roofing panel of the first group is formed by the back layer. For example, roofing panel 700, the back layer 720 forms color-matching surface 742. Such a back layer may be formed of a colored polymer material. For example, back layer 720 may be formed of any of the materials described above for the visible layer that is formed as an opaque substrate.

As stated above, each of the roofing panels in the second group is a cuttable non-solar roofing panel and includes a cuttable substrate. The term cuttable, as used herein, refers to a panel that can be cut by a mechanical process along a predetermined path, so as to have an intended geometry. For example, the cuttable substrate can be cut without shattering and without requiring a laser cutter or other thermal cutting tool.

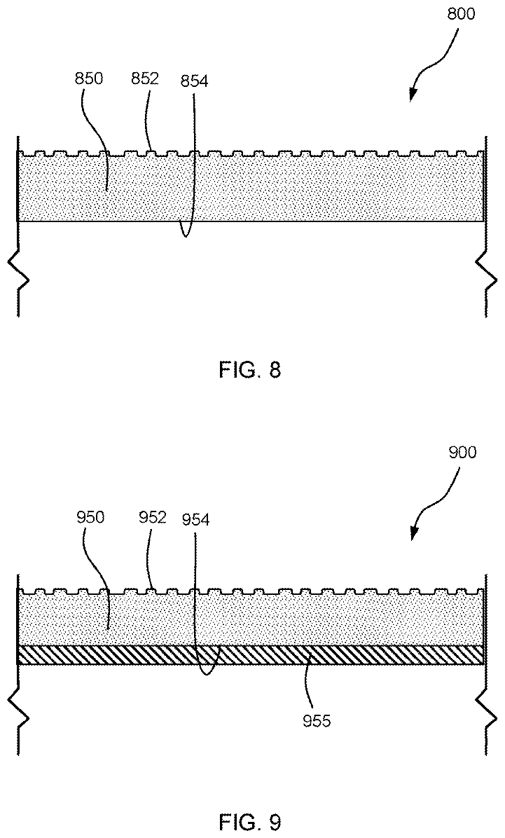

FIG. 8 illustrates a portion of a cross section of an embodiment of such a roofing panel. Roofing panel 800 includes an opaque cuttable substrate 850 having a front surface 852 and a rear surface 854. In some embodiments, the cuttable non-solar roofing panel includes a reinforcement layer. For example, roofing panel 900, shown in FIG. 9, includes an opaque cuttable substrate 950 including a front surface 952 and a rear surface 954. A mechanical reinforcement layer 955 is secured to the rear surface 954 of opaque cuttable substrate 950 and improves impact resistance of roofing panel 900. The mechanical reinforcement layer may be formed of a polymer, such as a fiber-reinforced polymer.

In certain embodiments of the roofing system as otherwise described herein, the cuttable substrate is formed of a ceramic material. For example, in some embodiments the cuttable substrate of the cuttable non-solar roofing panel is formed of porcelain. In other embodiments, the cuttable substrate is formed of another material, such as glass or plastic. For example, the cuttable substrate may be formed of a glass other than tempered glass. The cuttable substrate may include a pigment or additive to hinder light transmission.

In some embodiments, the material of the cuttable substrate provides visual characteristics to the cuttable roofing panel that match those of the solar roofing panels. In other embodiments, the cuttable substrate may include a coating that provides the matching visual characteristics.

In some embodiments, materials of the cuttable roofing panels are configured such that the roofing panels are cuttable using a tile cutter. For example, the cuttable roofing panels may be formed of materials that can be scored with a tool to define a desired cutting edge and then broken along the scored edge. Such a technique is commonly used to cut ceramic tiles, as understood by those of ordinary skill in the art. As those of skill in the art will appreciate, there are a variety of tools that may be used to cut such panels, and these may include manual cutters that comprise a scoring blade or wheel, powered cutters that comprise a rotating circular blade, powered cutters that comprise a rotating end mill, powered cutters that comprise an oscillating tool, and manual cutters such as a tile nipper or scissoring tool.

In certain embodiments of the roofing system as otherwise described herein, the roofing panels are arranged in rows on a support structure. For example, the roofing panels 100A-100C of roofing system 190 are arranged in an array that includes a plurality of rows or courses 194 on support structure 192. In the embodiment of roofing system 190, the roofing panels 100A-100C in each row extend across the support structure. However, in other embodiments, the rows may extend up the slope of the roof. Further, while the roofing panels of each row 194 in roofing system 190 are offset from the roofing panels of a neighboring row, in other embodiments, the roofing panels of neighboring rows may be aligned so as to form a grid. Further still, while the roofing panels 100A-100C of roofing system 190 are flat and rectangular, such that the rows 194 have straight edges, in other embodiments, the roofing panels may have other polygonal shapes or be rounded. Moreover, in some embodiments, the surfaces of the roofing panels may bend or curve.

In certain embodiments of the roofing system as otherwise described herein, each roofing panel of the second group is disposed at the end of a row. For example, in roofing system 190, as shown in FIG. 1, each of the roofing panels 100B in the second group is positioned at the end of a row 194. In other embodiments, the roofing panels of the second group of roofing panels are positioned at another position within the array of the plurality of roofing panels, such as in the middle of a row. It should be understood that the described groups of panels do not necessarily include every panel in the roofing system with a particular characteristic. For example, while each of the roofing panels of the second group might be positioned at the end of a row, some of rows may include panels at their ends that are not part of the second group. Likewise, while each of the roofing panels of the first group might be solar panels, the roofing system may include other solar panels that are not a part of the first group.

In certain embodiments of the roofing system as otherwise described herein, each roofing panel of the second group includes a manufactured edge and a cut edge. For example, in roofing system 190, each of the roofing panels 100B of the second group has been cut from a roofing panel having the same size as roofing panels 100A. Accordingly, each of the roofing panels 100B of the second group has a cut edge on one side and a manufactured edge on the other side.

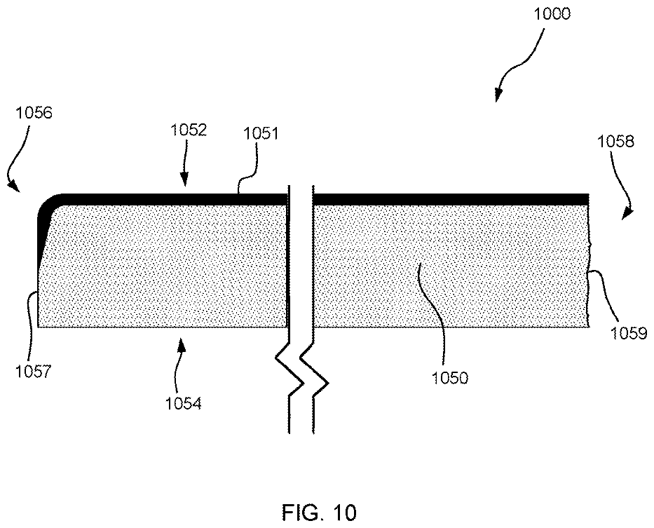

A schematic depiction of an embodiment of a roofing panel with a manufactured edge and a cut edge is shown in FIG. 10. Roofing panel 1000 includes an opaque cuttable substrate 1050 with a front surface 1052 and a rear surface 1054. The opaque cuttable substrate 1050 includes a manufactured edge 1056 along one side and a cut edge 1058 along the other side. While the illustrated manufactured edge 1056 and cut edge 1058 of opaque cuttable substrate 1050 are disposed on opposing sides of the panel, in other embodiments, the panel may have been cut along both sides. In such a case, the roofing panel may still have cut edges along two sides but manufactured edges along the top and bottom.

In certain embodiments of the roofing system as otherwise described herein, the cut edge has a greater roughness than the manufactured edge. For example, in some embodiments the manufactured edge has a smooth or polished surface whereas the cut edge has a fractured surface that is determined by the fracture mechanics of the material of the cuttable substrate. Further, in some embodiments, the cut edge has surface characteristics representative of the tool used to form the cut edge.

In certain embodiments of the roofing system as otherwise described herein, a coating extends over a first edge surface of the cuttable substrate at the manufactured edge, and a second edge surface of the opaque substrate at the cut edge is free of the coating. For example, roofing panel 1000, as shown in FIG. 10, includes a coating 1051 that extends over front surface 1052. At manufactured edge 1056, the coating 1051 extends from the front surface 1052 over the edge surface 1057. In contrast, because cut edge 1058 is formed after the application of coating 1051 to the front surface 1052, the edge surface 1059 at the cut edge 1058 is free of the coating 1051.

In some embodiments, the coating is a glaze. In other embodiments, the coating is a paint or another layer configured to modify the visual characteristics of the roofing panel.

In certain embodiments of the roofing system as otherwise described herein, the roofing panels in the second group have a smaller width than the roofing panels in the first group. For example, in roofing system 190 shown in FIG. 1, because each of the roofing panels 100B in the second group is cut from a panel that is the same size as roofing panels 100A of the first group, each of the roofing panels 100B has a reduced width compared to roofing panels 100A.

In certain embodiments of the roofing system as otherwise described herein, the roofing system further includes a third group of roofing panels, wherein each roofing panel of the third group is a non-solar roofing panel. For example, roofing system 190 shown in FIG. 1, includes a third group 100C of roofing panels each of which is a non-solar roofing panel.

In some embodiments, each roofing panel of the third group includes the same layers as the roofing panels of the second group. For example, in some embodiments, the roofing panels of the third group may be formed in a configuration similar to roofing panel 800 of FIG. 8 or similar to roofing panel 900 of FIG. 9.

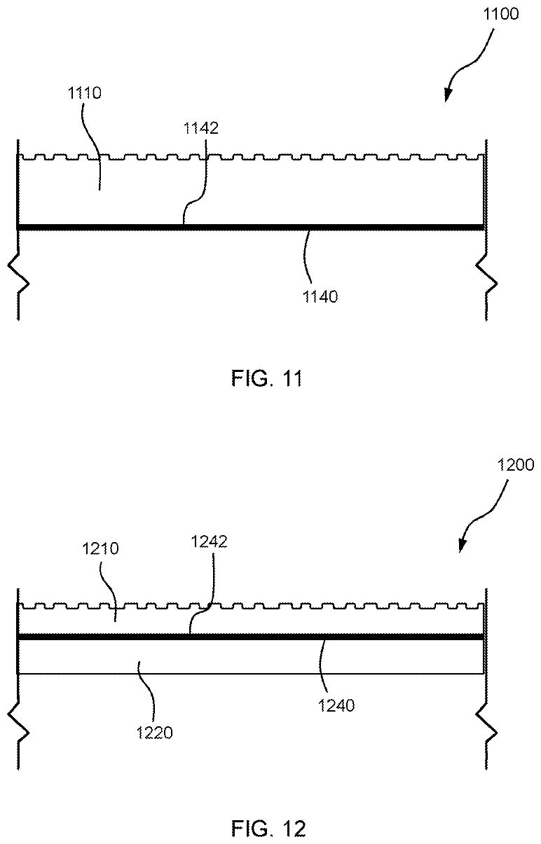

In other embodiments, each roofing panel of the third group includes a front layer of glass having a front surface and a rear surface, and a visible layer forming a color-matching surface disposed behind the front layer of glass. FIGS. 11 through 14 each illustrate a portion of a cross section of an embodiment of such a roofing panel.

In certain embodiments of the roofing system as otherwise described herein, each roofing panel of the third group includes a single glass layer formed by the front layer of glass. For example, FIG. 11 shows a portion of a cross section of a roofing panel 1100 that includes a single layer of glass 1110 that forms the front face of roofing panel 1100 and a visible layer 1140 that forms a color-matching surface 1142 disposed behind the front layer of glass 1110.

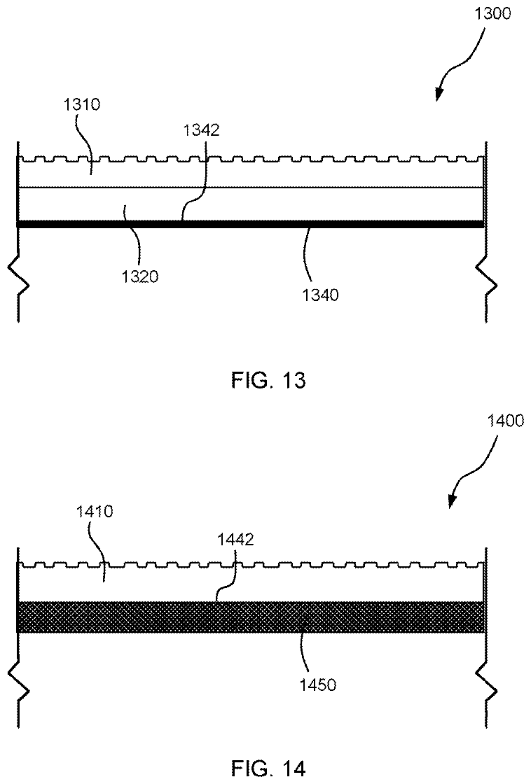

In certain embodiments of the roofing system as otherwise described herein, each roofing panel of the third group further includes a back layer of glass. Further, in some embodiments, the visible layer of each roofing panel in the third group is disposed between the front layer of glass and the back layer of glass. Such an embodiment is shown in FIG. 12. Roofing panel 1200 includes a front layer of glass 1210, a back layer of glass 1220, and a visible layer 1240 disposed between the front layer of glass 1210 and the back layer of glass 1220. The visible layer 1240 forms a color-matching surface 1242. In other embodiments, the visible layer of each roofing panel of the third group is disposed behind the back layer of glass. For example, roofing panel 1300, shown in FIG. 13, includes a front layer of glass 1310, a back layer of glass 1320, and a visible layer 1340 that forms a color-matching surface 1342 disposed behind the back layer of glass 1320.

In certain embodiments of the roofing system as otherwise described herein, the visible layer of each roofing panel of the third group is formed by a coating. For example, in some embodiments, the visible layer may be coated over a surface of the front or back layer. In such an embodiment, the respective layer of glass may provide structural support for the coated layer. Accordingly, the visible layer may be applied as a liquid or a film over the respective layer of glass. In some embodiments, the visible layer may be provided directly on a surface of the layer of glass or on an intermediate layer provided over the layer of glass. In some embodiments, the visible layer in each roofing panel of the third group is an inorganic enamel coating. In other embodiments, the visible layer in each roofing panel of the third group is another type of coating.

Alternatively, in some embodiments, the visible layer of each roofing panel of the third group is formed by an opaque substrate. In some embodiments, the opaque substrate is formed by a polymer layer. Such an embodiment is shown in FIG. 14. Roofing panel 1400 includes a front layer of glass 1410 and an opaque substrate 1450 disposed behind the front layer of glass 1410 that forms a color-matching surface 1442.

In certain embodiments of the roofing system as otherwise described herein, the front layer of the roofing panels of the third group has the same configuration as the front layer of the roofing panels of the first group. For example, in some embodiments, the layers are made of the same materials and the manufacturing specifications of the front layer of the solar panels of the first group is the same as the manufacturing specifications of the front layer of the non-solar panels of the third group. By providing the roofing panels of the first group and the roofing panels of the third group with front layers having the same configurations, the visual characteristics of the panels can be effectively matched to one another.

In certain embodiments of the roofing system as otherwise described herein, each roofing panel in the plurality of roofing panels has a thickness, and the thicknesses of the roofing panels differ by no more than the 4 mm, e.g., no more than 3 mm, e.g., no more than 2 mm. For example, in some embodiments, the solar roofing panels of the first group, the cuttable non-solar roofing panels of the second group, and any other roofing panels in the roofing system have substantially the same thickness. Accordingly, the same attachment configuration can be used across the surface of the roof without creating a perceivable difference in the height of the roofing panels.

In certain embodiments of the roofing system as otherwise described herein, each roofing panel in the plurality of roofing panels has a thickness in a range from 3 mm to 15 mm, e.g., from 3 to 9 mm. For example, in some embodiments, some of the roofing panels of the roofing system are thicker than others, but all of the roofing panels in the plurality of roofing panels have a thickness that falls within a predefined range.

The matching visual characteristics of the roofing panels of the first group and the roofing panels of the second group may be provided by similar color, similar gloss values, or similar textures.

For example, in certain embodiments of the roofing system as otherwise described herein, a front face of each roofing panel in the plurality of roofing panels presents a color, and wherein the colors of the front faces of the roofing panels vary by a color difference CIEDE2000 of no more than 10 as measured according to the CIE Colorimetry Technical Report (4^{th} Edition) using a 2° standard colorimetric observer, a CIE standard illuminant D65, and any of di:8°, de:8° or 45 degree directional geometry. In some embodiments, the front faces of the roofing panels have a color difference CIEDE2000, as measured under these same conditions, of no more than 6, for example no more than 3.

In certain embodiments of the roofing system as otherwise described herein, a front face of each roofing panel in the plurality of roofing panels has a gloss value as measured according to ASTM D523-08 using an appropriate geometry, and the gloss values of the front faces of the roofing panels vary by no more than 20 gloss units, e.g., no more than 10 gloss units, e.g., no more than 5 gloss units. For example, as explained in ASTM D523-08, where the gloss values using a 60° geometry are above 70, the values should be measured using a 20° geometry.

In certain embodiments of the roofing system as otherwise described herein, a front face of each roofing panel in the plurality of roofing panels has a textured surface. For example, in some embodiments, the front face of each roofing panel includes a plurality of protrusions and indentations that form a textured surface. Further, in some embodiments, the protrusions and indentations are formed as ridges and grooves that extend across the surface. In other embodiments, the front surface of the roofing panels may be flat. Further, in some embodiments, some of the roofing panels may include a front face with a texture while others include a front face that is flat. Further, in some embodiments, the roofing panels with a flat front face may include an image of a texture to visibly match the roofing panels that include a texture.

In certain embodiments of the roofing system as otherwise described herein, the topography of the textured surface of the roofing panels in different groups is substantially the same. For example, in some embodiments, the textured surface of each roofing panel in the plurality of roofing panels has an average protrusion width, and the average protrusion widths of the roofing panels vary by no more than 25%, e.g., no more than 10%. Likewise, in some embodiments, the textured surface of each roofing panel in the plurality of roofing panels has an average indentation width, and the average indentation widths of the roofing panels vary by no more than 25%, e.g., no more than 10%. Further, in some embodiments, the textured surface of each roofing panel in the plurality of roofing panels has an average protrusion height, and the average protrusion heights of the roofing panels vary by no more than 25%, e.g., no more than 10%. Further, in some embodiments, the textured surface of each roofing panel in the plurality of roofing panels has an average indentation depth, and the average indentation depths of the roofing panels vary by no more than 25%, e.g., no more than 10%.

In another aspect, the disclosure provides a method of installing a roofing system according to the disclosure. The method includes arranging a first group of roofing panels on a support structure, cutting a plurality of other roofing panels so as to form a second group of roofing panels, and arranging the second group of roofing panels on the support structure. Each roofing panel of the first group is a solar roofing panel and includes a front layer having a front surface and a rear surface, a back layer having a front surface and a rear surface, photovoltaic cells disposed between the rear surface of the front layer and the front surface of the back layer, and a color-matching surface disposed behind the front layer. Each roofing panel of the second group is a cuttable non-solar roofing panel and includes a cuttable substrate. Further, visual characteristics of a front face of the roofing panels of the first group and a front face of roofing panels of the second group match.

In certain embodiments of the method as otherwise described herein, cutting the plurality of other roofing panels includes scoring a surface of each of the other roofing panels to form a fracture line and breaking the other roofing panels along the fracture line. For example, in some embodiments, the roofing panels of the second group are formed using a tile cutter. In other embodiments, cutting the other roofing panels may be performed using another cutting tool, such as a powered cutting tool. Further still, in some embodiments, cutting the other roofing panels may be performed using a thermal cutting tool, such as a laser cutter, though the other panels should be capable of being cut by a mechanical process.

In certain embodiments of the method as otherwise described herein, the method further includes arranging a third group of roofing panels on the support structure, wherein each roofing panel of the third group is a non-solar roofing panel. For example, in some embodiments, the roofing panels of the third group are formed from the same type of roofing panel as the roofing panels of the second group, but are uncut. Alternatively, in some embodiments each roofing panel of the third group includes a front layer of glass having a front surface and a rear surface, and a visible layer disposed behind the front layer of glass.

In certain embodiments of the method as otherwise described herein, arranging the first group of roofing panels on the support structure includes arranging the first group of roofing panels in rows or courses. For example, the installation of roofing system 190, shown in FIG. 1, includes arranging the roofing panels 100A of the first group into rows 194.

Further, in some embodiments, arranging the second group of roofing panels includes arranging the second group of roofing panels at the ends of the rows. For example, in the installation of roofing system 190, a roofing panel 100B of the second group is placed at the end of each row 194 at the edge of the support structure 192.

In certain embodiments of the method as otherwise described herein, arranging the third group of roofing panels includes arranging at least some of the third group of roofing panels between the first group of roofing panels and the second group of roofing panels. For example, in the installation of roofing system 190, a roofing panel 100C of the third group is placed between a roofing panel 100A of the first group and a roofing panel 100B of the second group in each of the second, fourth, and sixth courses of roofing panels. In contrast, in the third, and fifth courses of roofing panels, a roofing panel 100A of the first group is placed adjacent to a roofing panel 100B of the second group.

It will be apparent to those skilled in the art that various modifications and variations can be made to the processes and devices described here without departing from the scope of the disclosure. Thus, it is intended that the present disclosure cover such modifications and variations of this invention provided they come within the scope of the appended claims and their equivalents.

Many different aspects and embodiments are possible. Some of those aspects and embodiments are described herein. After reading this specification, skilled artisans will appreciate that those aspects and embodiments are only illustrative and do not limit the scope of the present invention. Embodiments may be in accordance with any one or more of the embodiments as listed below.

Embodiment 1. A roofing system comprising a plurality of roofing panels comprising: a first group of roofing panels, wherein each roofing panel of the first group is a solar roofing panel and includes: a light transmissible front layer having a front surface and a rear surface, a back layer having a front surface and a rear surface, photovoltaic cells disposed between the rear surface of the front layer and the front surface of the back layer, and a color-matching surface disposed behind the front layer; a second group of roofing panels, wherein each roofing panel of the second group is a cuttable non-solar roofing panel and includes: a cuttable substrate, wherein visual characteristics of a front face of the roofing panels of the first group and a front face of roofing panels of the second group match.

Embodiment 2. The roofing system according to embodiment 1, wherein the color-matching surface of each roofing panel of the first group is formed by a coating.

Embodiment 3. The roofing assembly according to embodiment 2, wherein the coating includes a pattern associated with the shape of the photovoltaic cells and is applied over: the rear surface of the front layer, the front surface of the back layer, or the rear surface of back layer.

Embodiment 4. The roofing system according to embodiment 2, wherein the coating extends across the roofing panel and is applied over the front surface of the back layer or the rear surface of the back layer.

Embodiment 5. The roofing assembly according to any of embodiments 2 to 4, wherein the coating is an inorganic enamel coating.

Embodiment 6. The roofing system according to embodiment 1, wherein the color-matching surface of each roofing panel of the first group is formed by an opaque substrate.

Embodiment 7. The roofing system according to embodiment 6, wherein the opaque substrate is disposed between the photovoltaic cells and the back layer.

Embodiment 8. The roofing system according to embodiment 6, wherein the opaque substrate is disposed behind the back layer.

Embodiment 9. The roofing system according to any of embodiments 6 to 8, wherein the opaque substrate is formed of a polymer material.

Embodiment 10. The roofing system according to embodiment 1, wherein the color-matching surface of each roofing panel of the first group is formed by the back layer.

Embodiment 11. The roofing system according to any of embodiments 1 to 10, wherein at least one of the front layer and the back layer of each roofing panel of the first group is formed of glass, e.g., tempered glass.

Embodiment 12. The roofing system according to any of embodiments 1 to 11, wherein the cuttable substrate is formed of a ceramic material.

Embodiment 13. The roofing system according to embodiment 12, wherein the cuttable substrate is porcelain.

Embodiment 14. The roofing system according to any of embodiments 1 to 13, wherein each roofing panel of the second group is cuttable using a tile cutter.

Embodiment 15. The roofing system according to any of embodiments 1 to 14, wherein the roofing panels are arranged in rows on a support structure.

Embodiment 16. The roofing system according to embodiment 15, wherein each roofing panel of the second group is disposed at an end of a row.

Embodiment 17. The roofing system according to embodiment 15 or embodiment 16, wherein each roofing panel of the second group includes a manufactured edge and a cut edge.

Embodiment 18. The roofing system according to embodiment 17, wherein the cut edge has a greater roughness than the manufactured edge.

Embodiment 19. The roofing system according to embodiment 17 or embodiment 18, wherein a coating extends over a first edge surface of the cuttable substrate at the manufactured edge, and wherein a second edge surface of the cuttable substrate at the cut edge is free of the coating.

Embodiment 20. The roofing system according to embodiment 19, wherein the coating is a glaze.

Embodiment 21. The roofing system according to any of embodiments 1 to 20, wherein the roofing panels in the second group have a smaller width than the roofing panels in the first group.

Embodiment 22. The roofing system according to any of embodiments 1 to 21, further comprising a third group of roofing panels, wherein each roofing panel of the third group is a non-solar roofing panel.

Embodiment 23. The roofing system according to embodiment 22, wherein each roofing panel of the third group includes the same layers as the roofing panels of the second group.

Embodiment 24. The roofing system according to embodiment 22, wherein each roofing panel of the third group includes: a front layer having a front surface and a rear surface, and a visible layer including a color-matching surface disposed behind the front layer.

Embodiment 25. The roofing system according to embodiment 24, wherein each roofing panel of the third group includes a single glass layer formed by the front layer.

Embodiment 26. The roofing system according to embodiment 24, wherein each roofing panel of the third group further includes a back layer of glass.

Embodiment 27. The roofing system according to embodiment 26, wherein the visible layer is disposed between the front layer and the back layer of glass.

Embodiment 28. The roofing system according to embodiment 26, wherein the visible layer of each roofing panel of the third group is disposed behind the back layer of glass.

Embodiment 29. The roofing system according to any of embodiments 24 to 28, wherein the visible layer of each roofing panel of the third group is formed by a coating.

Embodiment 30. The roofing system according to embodiment 29, wherein the coating is an inorganic enamel coating.

Embodiment 31. The roofing system according to any of embodiments 24 to 28, wherein the visible layer of each roofing panel of the third group is formed by an opaque substrate.

Embodiment 32. The roofing system according to embodiment 31, wherein the opaque substrate of the visible layer is formed by a polymer layer.

Embodiment 33. The roofing system according to any of embodiments 24 to 32, wherein the front layer of the roofing panels of the third group has the same configuration as the front layer of the roofing panels of the first group.

Embodiment 34. The roofing system according to any of embodiments 1 to 33, wherein each roofing panel in the plurality of roofing panels has a thickness, and wherein the thicknesses of the roofing panels differ by no more than the 4 mm, e.g., no more than 3 mm, e.g., no more than 2 mm.

Embodiment 35. The roofing system according to any of embodiments 1 to 34,wherein each roofing panel in the plurality of roofing panels has a thickness in a range from 3 mm to 15 mm, e.g., from 3 to 9 mm.

Embodiment 36. The roofing system according to any of embodiments 1 to 35, wherein a front face of each roofing panel in the plurality of roofing panels has a color, and wherein the colors of the front faces of the roofing panels vary by a color difference CIEDE2000 of no more than 10.

Embodiment 37. The roofing system according to any of embodiments 1 to 36, wherein a front face of each roofing panel in the plurality of roofing panels has a gloss value, and wherein the gloss values of the front faces of the roofing panels vary by no more than 20 gloss units, e.g., no more than 10 gloss units, e.g., no more than 5 gloss units.

Embodiment 38. The roofing system according to any of embodiments 1 to 37, wherein a front face of each roofing panel in the plurality of roofing panels has a textured surface.

Embodiment 39. The roofing system according to embodiment 38, wherein the textured surface includes a plurality of protrusions and indentations.

Embodiment 40. The roofing system according to embodiment 39, wherein the textured surface of each roofing panel in the plurality of roofing panels has an average protrusion width, and wherein the average protrusion widths of the roofing panels vary by no more than 25%, e.g., no more than 10%.

Embodiment 41. The roofing system according to embodiment 39 or embodiment 40, wherein the textured surface of each roofing panel in the plurality of roofing panels has an average indentation width, and wherein the average indentation widths of the roofing panels vary by no more than 25%, e.g., no more than 10%.

Embodiment 42. The roofing system according to any of embodiments 39 to 41, wherein the textured surface of each roofing panel in the plurality of roofing panels has an average protrusion height, and wherein the average protrusion heights of the roofing panels vary by no more than 25%, e.g., no more than 10%.

Embodiment 43. The roofing system according to any of embodiments 39 to 42, wherein the textured surface of each roofing panel in the plurality of roofing panels has an average indentation depth, and wherein the average indentation depths of the roofing panels vary by no more than 25%, e.g., no more than 10%.

Embodiment 44. A method of installing a roofing system according to any of embodiments 1 to 43, the method comprising: arranging a first group of roofing panels on a support structure, wherein each roofing panel of the first group is a solar roofing panel and includes: a front layer having a front surface and a rear surface, a back layer having a front surface and a rear surface, photovoltaic cells disposed between the rear surface of the front layer and the front surface of the back layer, and a color-matching surface disposed behind the front layer; cutting a plurality of other roofing panels so as to form a second group of roofing panels, wherein each roofing panel of the second group is a cuttable non-solar roofing panel and includes a cuttable substrate; and arranging the second group of roofing panels on the support structure; wherein visual characteristics of a front face of the roofing panels of the first group and a front face of roofing panels of the second group match.

Embodiment 45. The method according to embodiment 44, wherein cutting the plurality of other roofing panels includes scoring a surface of each of the other roofing panels to form a fracture line and breaking the other roofing panels along the fracture line.

Embodiment 46. The method according to embodiment 45, wherein the plurality of other roofing panels are cut using a tile cutter.

Embodiment 47. The method according to any of embodiments 44 to 46, further comprising arranging a third group of roofing panels on the support structure, wherein each roofing panel of the third group is a non-solar roofing panel.

Embodiment 48. The method according to embodiment 47, wherein each roofing panel of the third group includes the same layers as the roofing panels of the second group.

Embodiment 49. The method according to embodiment 47, wherein each roofing panel of the third group includes: a front layer having a front surface and a rear surface, and a visible layer including a color-matching surface disposed behind the front layer.

Embodiment 50. The method according any of embodiments 44 to 49, wherein arranging the first group of roofing panels on the support structure includes arranging the first group of roofing panels in rows.

Embodiment 51. The method according to embodiment 50, wherein arranging the second group of roofing panels includes arranging the second group of roofing panels at the ends of the rows.

Embodiment 52. The method according to embodiment 51, wherein arranging the third group of roofing panels includes arranging at least some of the third group of roofing panels between the first group of roofing panels and the second group of roofing panels.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A roofing system comprising a plurality of roofing panels comprising:
a first group of roofing panels, wherein each roofing panel of the first group is a solar roofing panel and includes:
a light transmissible front layer having a front surface and a rear surface,
a back layer having a front surface and a rear surface,
photovoltaic cells disposed between the rear surface of the front layer and the front surface of the back layer, and
a color-matching surface disposed behind the front layer;
a second group of roofing panels, wherein each roofing panel of the second group is a cuttable non-solar roofing panel and includes:
a cuttable substrate,
wherein visual characteristics of a front face of the roofing panels of the first group and a front face of roofing panels of the second group match.

2. The roofing system according to claim 1, wherein the color-matching surface of each roofing panel of the first group is formed by a coating.

3. The roofing system according to claim 2, wherein the coating includes a pattern associated with the shape of the photovoltaic cells and is applied over:
the rear surface of the front layer,
the front surface of the back layer, or
the rear surface of back layer.

4. The roofing system according to claim 2, wherein the coating extends across the roofing panel and is applied over the front surface of the back layer or the rear surface of the back layer.

5. The roofing system according to claim 2 wherein the coating is an inorganic enamel coating.

6. The roofing system according to claim 1, wherein the color-matching surface of each roofing panel of the first group is formed by an opaque substrate.

7. The roofing system according to claim 6, wherein the opaque substrate is disposed between the photovoltaic cells and the back layer.

8. The roofing system according to claim 6, wherein the opaque substrate is disposed behind the back layer.

9. The roofing system according to claim 6, wherein the opaque substrate is formed of a polymer material.

10. The roofing system according to claim 1, wherein the color-matching surface of each roofing panel of the first group is formed by the back layer.

11. The roofing system according to claim 1, wherein at least one of the front layer and the back layer of each roofing panel of the first group is formed of glass.

12. The roofing system according to claim 1, wherein the cuttable substrate is formed of a ceramic material.

13. The roofing system according to claim 12, wherein the cuttable substrate is porcelain.

14. A method of installing a roofing system according to claim 1, the method comprising:
arranging a first group of roofing panels on a support structure, wherein each roofing panel of the first group is a solar roofing panel and includes:
a front layer having a front surface and a rear surface,
a back layer having a front surface and a rear surface,
photovoltaic cells disposed between the rear surface of the front layer and the front surface of the back layer, and
a color-matching surface disposed behind the front layer;
cutting a plurality of other roofing panels so as to form a second group of roofing panels, wherein each roofing panel of the second group is a cuttable non-solar roofing panel and includes a cuttable substrate; and
arranging the second group of roofing panels on the support structure;
wherein visual characteristics of a front face of the roofing panels of the first group and a front face of roofing panels of the second group match.

15. The method according to claim 14, wherein cutting the plurality of other roofing panels includes scoring a surface of each of the other roofing panels to form a fracture line and breaking the other roofing panels along the fracture line.

16. The method according to claim 15, wherein the plurality of other roofing panels are cut using a tile cutter.

17. The method according to claim 14, further comprising arranging a third group of roofing panels on the support structure, wherein each roofing panel of the third group is a non-solar roofing panel.

18. The method according to claim 17, wherein each roofing panel of the third group includes the same layers as the roofing panels of the second group.

19. The method according to claim 17, wherein each roofing panel of the third group includes:
a front layer having a front surface and a rear surface, and
a visible layer including a color-matching surface disposed behind the front layer.

20. The method according to claim 14, wherein arranging the first group of roofing panels on the support structure includes arranging the first group of roofing panels in rows.
